(19) United States
(12) Patent Application Publication
(10) Pub. No.: US 2002/0110034 A1
(43) Pub. Date: Aug. 15, 2002

(54) Input-output circuit and current control circuit of semiconductor memory device

(75) Inventors: Ki-Hwan Song, Seoul (KR); Dae-Woon Kang, Yongin-city (KR)

Correspondence Address: Anthony P. Onello, Jr., MILLS & ONELLO LLP, Eleven Beacon Street, Suite 605, Boston, MA, 02108, US

(73) Assignee: Samsung Electronics Co., Ltd.

(21) Appl. No.: 09/950,962

(22) Filed: Sep. 12, 2001

(30) Foreign Application Priority Data
Feb. 14, 2001 (KR) 01-7271

(51) Int. Cl. G11C 5/00

(52) U.S. Cl. 365/226

(57) ABSTRACT

An input-output circuit and a current control circuit of a semiconductor memory device which is insensitive to variations in manufacturing process, in voltage levels of input-output pins, and in temperature, and can prevent undesired effects such as an excess of leakage current during operation in a test mode such as a burn-in test. The current control circuit includes first and second transmitters having CMOS transmission gates, a voltage divider, a comparator, a current control counter, a first resistor connected between a bulk of a PMOS transistor of the first CMOS transmission gate and a DC voltage, and a second resistor connected between a bulk of a PMOS transistor of the second CMOS transmission gate and a DC voltage. The first and second resistors prevent current greater than a predetermined level from leaking even though PN diodes formed in the PMOS transistors of the first and second transmitters are forward biased. As a result, undesired effects such as an excess of leakage current are prevented in the test mode such as the burn-in test. Also, since the first and second transmitters include CMOS transmission gates, an NMOS transistor and a PMOS transistor of the CMOS transmission gate complement each other. Thus, the current control circuit is insensitive to variations in manufacturing process, in voltage levels of input-output pins, and in temperature.

### BACKGROUND OF THE INVENTION

1. Field of the Invention

The present invention relates to a semiconductor memory device, and more particularly, to an input-output circuit and a current control circuit of a packet type semiconductor memory device.

2. Description of the Related Art

Semiconductor memory devices, such as RamBus DRAMs, in which data and addresses are input in packet units, have been developed in order to realize high-speed operation. In a system adopting a packet type semiconductor memory device, a memory controller and a plurality of packet type semiconductor memory devices are connected to a plurality of signal lines which are generally referred to as channels. Thus, packet type semiconductor memory devices include a current control circuit for accurately controlling the current of an output driver, based on the magnitude of the load of an input pin connected to a given channel.

FIG. 1 is a drawing showing an input-output circuit of a packet type semiconductor memory device, and FIG. 2 is a drawing showing a conventional current control circuit for the circuit of FIG. 1. Referring to FIG. 1, a current control circuit 13 is connected to an output driver 14 for controlling current. The current control circuit 13 receives an output low voltage VOL of an input-output pin 11 and an output high voltage VOH of an input-output pin 12, obtains the average value of these voltages, determines whether the average value is greater or smaller than a predetermined voltage (for example input from an external source), and controls the current of an output driver 14 connected to the input-output pin 11 based on the determined results.

With reference to FIG. 2, the current control circuit 13 includes a first transmitter 23 for transmitting the low voltage VOL value of the input-output pin 11 in response to a current control enable signal CCE, a second transmitter 24 for transmitting the high voltage VOH value of the input-output pin 12 in response to the current control enable signal CCE, a voltage divider 25 for obtaining the average value Vcmp of the low voltage VOL transmitted through the first transmitter 23 and the high voltage VOH transmitted through the second transmitter 24, a comparator 26 for comparing the average value Vcmp with a reference voltage Vref, and a current control counter 27 for generating control bits ICTRO through ICTR5 for controlling the current of the output driver 14 in response to the output of the comparator 26.

Conventionally, the first and second transmitters 23 and 24 include CMOS type transmission gates or NMOS type pass gates. In a case where the first and second transmitters 23 and 24 include CMOS type transmission gates, since an NMOS transistor and a PMOS transistor of the CMOS type transmission gate complement each other, they offset each other against variations due to manufacturing process, voltage levels of the input-output pins 11 and 12, and temperature. Thus, the stability of the current control circuit is not dependent on variations in a manufacturing process, voltage levels of input-output pins, and temperature, i.e., stability of the current control circuit is improved. However, during a test mode such as a burn-in test where the supply voltage is about 2.5 volts and a voltage of greater than 4 volts is applied to the input-output pins 11 and 12, a PN diode formed in the PMOS transistor of the CMOS transmission gate is forward biased, which generates leakage current. As a result, an excess of leakage current may be generated during a burn-in test mode.

In a case where the first and second transmitters 23 and 24 include NMOS type pass gates, an excess of leakage current is not generated in a test mode such as a burn-in test. However, this configuration does not offer the advantage of an offset against variations in a manufacturing process, voltage levels of the input-output pins 11 and 12, and temperature. Thus, the stability of the current control circuit is dependent on variations in a manufacturing process, voltage levels of the input-output pins 11 and 12, and temperature, i.e., stability is degraded.

### SUMMARY OF THE INVENTION

To address the above limitations, it is a first object of the present invention to provide a current control circuit for a semiconductor memory device which is insensitive to variations in a manufacturing process, voltage levels of input-output pins, and temperature and can further prevent undesired effects such as an excess of leakage current during operation in a test mode, such as a burn-in test.

It is a second object of the present invention to provide an input-output circuit of a semiconductor memory device which is insensitive to variations in manufacturing process, voltage levels of input-output pins, and temperature, and further can prevent undesired effects such as an excess of leakage current during operation in a test mode, such as a burn-in test.

Accordingly, to achieve the above first object, there is provided a current control circuit of a semiconductor memory device. The current control circuit includes first and second transmitters formed of CMOS transmission gates, first and second resistors, a voltage divider, comparator, and a current control counter. The first resistor is connected between a bulk of a PMOS transistor of the first CMOS transmission gate and a DC voltage. The second resistor is connected between a bulk of a PMOS transistor of the second CMOS transmission gate and a DC voltage. The first CMOS transmission gate transmits a low voltage VOL output from the first input-output pin in response to a current control enable signal. The second CMOS transmission gate transmits a high voltage VOH output from a second input-output pin in response to the current control enable signal. The first resistor prevents current greater than a predetermined level from leaking even though a PN diode formed between the PMOS transistor and the N-type bulk of the first transmitter is forward biased. The second resistor also prevents current greater than a predetermined level from leaking even though a PN diode formed between the PMOS transistor and the N-type bulk of the second transmitter is forward biased.

Preferably, the first and second resistors are formed of an N-type well or polysilicon. The voltage divider obtains an average voltage value of the voltages in response to voltages transmitted through the first and second CMOS transmission gates. The comparator compares the average value with a reference voltage. The current control counter generates control bits for controlling the current of the output driver in response to the output of the comparator.

To achieve the second object, there is provided an input-output circuit of a semiconductor memory device connected to an input-output pin. The input-output circuit includes: a PMOS transistor having a source and drain, one of which is connected to the input-output pin, the PMOS transistor for transmitting the voltage of the input-output pin in response to a predetermined control signal; and a resistor connected to between bulk of the PMOS transistor and a DC voltage. The resistor is formed of an N-type well corresponding to the bulk of the PMOS transistor or polysilicon.

### BRIEF DESCRIPTION OF THE DRAWINGS

The above objectives and advantages of the present invention will become more apparent by describing in detail, preferred embodiments thereof with reference to the attached drawings in which:

FIG. 1 is a schematic illustration of an input-output circuit of a packet type semiconductor memory device;

FIG. 2 is a schematic illustration of a conventional current control circuit for the circuit of FIG. 1; and

FIG. 3 is a schematic illustration of a current control circuit of a semiconductor memory device according to an embodiment of the present invention.

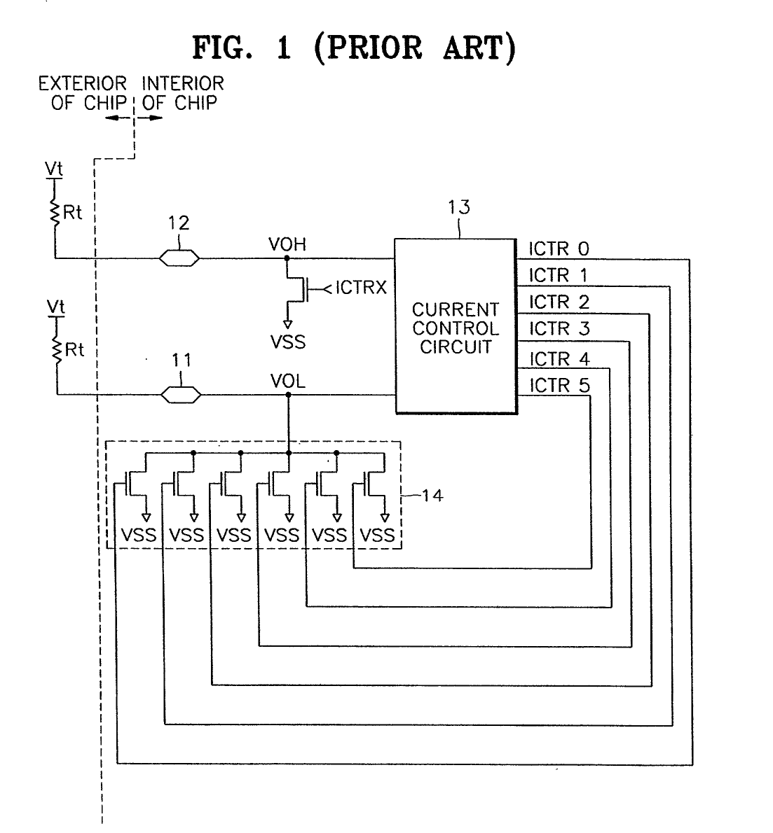

### DETAILED DESCRIPTION OF PREFERRED EMBODIMENTS

Hereinafter, a preferred embodiment of the present invention will be described in detail with reference to the attached drawings. Like reference numerals in the drawings denote the same members.

Referring to FIG. 3, a current control circuit according to an embodiment of the present invention includes first and second transmitters 33 and 34 having CMOS type transmission gates, a voltage divider 35, a comparator 36, and a current control counter 37. In particular, the current control circuit further includes a resistor R33 connected between an N-type bulk of a PMOS transistor of the first transmitter 33 and a supply voltage VDD, and a resistor R34 connected between an N-type bulk of a PMOS transistor of the second transmitter 34 and the supply voltage VDD.

The first transmitter 33 transmits a low voltage VOL output from a first input-output pin 31 in response to a current control enable signal CCE. The second transmitter 34 transmits a high voltage VOH output from a second input-output pin 32 in response to the current control enable signal CCE. The first transmitter 33 and the resistor R33 comprise an input-output circuit connected to the first input-output pin 31. The second transmitter 34 and the resistor R34 comprise an input-output circuit connected to the second input-output pin 32.

When the current control enable signal CCE is activated, it has a high voltage VPP value that his higher than the supply voltage VDD in order to reduce the voltage drop of the low voltage VOL transmitted through the first transmitter 33 and the voltage drop of the high voltage VOH transmitted through the second transmitter 34.

The voltage divider 35 obtains an average value Vcmp of the voltages in response to the low voltage VOL transmitted through the first transmitter 33 and the high voltage VOH transmitted through the second transmitter 34. The voltage divider 35, which is a resistor ladder type divider, includes resistors R31 and R32 connected to each other in series between an output terminal of the first transmitter 33 and an output terminal of the second transmitter 34 and outputs the average value Vcmp at the junction between the resistors R31 and R32. The resistors R31 and R32 have the same resistance values and thus the average value Vcmp becomes (VOH+VOL)/2.

The comparator 36 compares the average value Vcmp with an externally-applied reference value Vref. The current control counter 37 generates control bits ICTR0 through ICTR5 for controlling the current of an output driver (not shown) connected to the first input-output pin 31, in response to the output of the comparator 36. The control bits ICTR0 through ICTR5 turn NMOS pull-down transistors of an output driver on or off to control the current of the output driver. The control operation of the current of the output driver is well known to one skilled in the art and thus it will be omitted.

It is preferable that resistors R33 and R34 be made of an N-type well or polysilicon structure. The resistor R33 prevents current levels greater than a predetermined level from leaking even though a PN diode formed between the PMOS transistor of the first transmitter 33 and the N-type bulk is forward biased during a test mode such as a burn-in test (Here, the supply voltage is about 2.5 volts and a voltage of greater than 4 volts is applied to the input-output pins 31 and 32). At the same time, resistor R34 also prevents currents greater than a predetermined level from leaking even though a PN diode formed between the PMOS transistor of the second transmitter 34 and the N-type bulk is forward biased in a test mode such as a burn-in test.

Accordingly, the input-output circuit and the current control circuit according to the present invention shown in FIG. 3 prevent undesired effects such as an excess of leakage current during operation in a test mode such as a burn-in test. In addition, the first and second transmitters 33 and 34 include CMOS transmission gates, and thus the NMOS transistors and PMOS transistors of CMOS transmission gates complement each other. As a result, the current control circuit according to the present invention is insensitive to variations in manufacturing process, in voltage levels of the input-output pins 31 and 32, and in temperature, and thus, stability is improved.

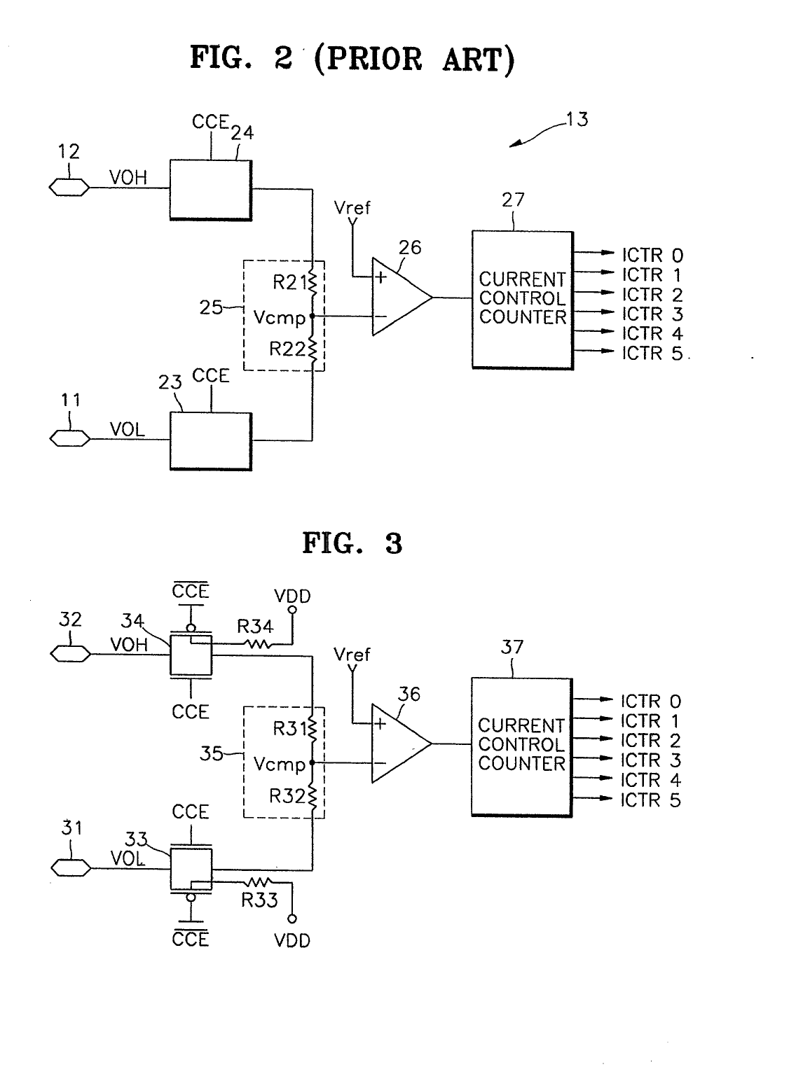

A simulation was performed under worst-case conditions in which the supply voltage VDD was 2.25 volts, a current control enable signal CCE applied to the first and second transmitters was 3.3 volts, and the temperature was 110° C. According to the results of the simulation, in the conventional current control circuit where first and second transmitters include NMOS type pass gates, as shown in FIG. 2, a maximum offset voltage of about ±18 millivolts is generated at the output terminal of a voltage divider which outputs the average value Vcmp. Also, in the current control circuit according to the present invention shown in FIG. 3, a maximum offset voltage of about ±8 millivolts is generated at the output terminal of a voltage divider which outputs the average value Vcmp. From these results, it is seen that the current control circuit of the present invention shown in FIG. 3 is relatively less sensitive to variations in manufacturing process, voltage levels of input-output pins, and temperature, as compared to the conventional current control circuit shown in FIG. 2.

As described above, the input-output circuit and the current control circuit according to the present invention can prevent undesired effects such as an excess of leakage current during operation in a test mode such as a burn-in test. Also, the input-output circuit and the current control circuit are insensitive to variations in manufacturing process, voltage levels of input-output pins, and temperature, i.e., stability is improved.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A current control circuit of a semiconductor memory device which controls the current of an output driver connected to a first input-output pin, the current control circuit comprising:
a first CMOS transmission gate for transmitting the voltage of the first input-output pin in response to a current control enable signal;
a second CMOS transmission gate for transmitting a voltage of a second input-output pin in response to the current control enable signal;
a first resistor connected between a bulk of a PMOS transistor of the first CMOS transmission gate and a DC voltage; and
a second resistor connected between a bulk of a PMOS transistor of the second CMOS transmission gate and the DC voltage;
a voltage divider for obtaining an average voltage value of the voltages in response to first and second voltages transmitted through the first and second CMOS transmission gates;
a comparator for comparing the average value with a reference voltage; and
a current control counter for generating control bits for controlling the current of the output driver in response to the output of the comparator.

2. The current control circuit of claim 1, wherein the first and second resistors are formed of an N-type well corresponding to the bulk of the PMOS transistors.

3. The current control circuit of claim 1, wherein the first and second resistors are formed of polysilicon.

4. An input-output circuit of a semiconductor memory device connected to an input-output pin, comprising:
a PMOS transistor having a source and drain, one of which is connected to the input-output pin, the PMOS transistor for transmitting the voltage of the input-output pin in response to a predetermined control signal; and
a resistor connected to between a bulk of the PMOS transistor and a DC voltage.

5. The input-output circuit of claim 4, wherein the resistor is formed of an N-type well corresponding to the bulk of the PMOS transistor.

6. The input-output circuit of claim 4, wherein the resistor is formed of polysilicon.
